(19) United States
(12) Patent Application Publication
(10) Pub. No.: US 2002/0137338 A1
(43) Pub. Date: Sep. 26, 2002

(54) Method for depositing copper films having controlled morphology and semiconductor wafers produced thereby

(75) Inventors: Tugrul Yasar, Scottsdale, AZ (US); Joseph T. Hillman, Scottsdale, AZ (US); Thomas Kandris, Fulsom, CA (US)

Correspondence Address: Kristi L. Davidson, Wood, Herron & Evans, L.L.P., 2700 Carew Tower, 441 Vine Street, Cincinnati, OH, 45202-2917, US

(73) Assignee: Tokyo Electron Limited

(21) Appl. No.: 09/817,590

(22) Filed: Mar. 26, 2001

(51) Int. Cl. H01L 23/48; B32B 15/00; H01L 29/12; H01L 21/44; H01L 29/40; H01L 23/52

(52) U.S. Cl. 438/687; 428/647; 428/652; 428/620; 428/649; 438/654; 438/680; 438/658; 257/753; 257/750

(57) ABSTRACT

Method for controlling the morphology and impeding electromigration of sputtered copper films and semiconductor wafers produced thereby. Copper may be deposited onto a seed layer or wetting layer of a dopant metal by PVD at an elevated temperature relative to the temperature at which the seed layer is deposited. Copper may also be deposited in a two step PVD process whereby a first copper layer is deposited at a lower temperature relative to a second copper layer. The resulting film has a smooth surface and no voids.

### FIELD OF THE INVENTION

The invention relates generally to methods of producing a controlled surface on a deposited copper film, and semiconductor wafers produced by those methods.

### BACKGROUND

In the formation of integrated circuits (IC), thin films containing metal and metalloid elements are deposited upon the surface of a semiconductor substrate or wafer. The films provide conductive and ohmic contacts in the circuits and between the various devices of an IC. For example, a thin film of a desired metal might be applied to the exposed surface of a contact or via in a semiconductor substrate. The film, passing through the insulative layers of the substrate, provides plugs of conductive material for the purpose of making interconnections across the insulating layers.

One well known process for depositing a thin metal film is by chemical vapor deposition (CVD). In CVD, reactant or deposition gases are pumped into proximity to a target and substrate inside a reaction chamber. The gases subsequently undergo chemical reactions at the surface of the target and substrate, resulting in one or more reaction by-products which are deposited on the exposed substrate or wafer surface to form a film. While CVD processes are often used, their use is sometimes less desirable due to their increased cost relative to other processes, such as physical vapor deposition (PVD) processes like sputtering.

The deposited film ideally has a smooth mirror-like surface. However, a significant problem in advanced integrated circuit metallization as in ultra large scale integration (ULSI) circuitry is controlling the surface roughness, or morphology, of a sputtered film such as a copper film. In fact, one disadvantage of using a sputtering method for integrated circuit metallization is the roughness of the resulting copper surface. The rough surface occurs because sputtering results in a relatively low density of copper nuclei, which grow rapidly to form large grains of copper. Even when copper is deposited by a PVD process, it is known that without a seed layer of copper deposited by chemical vapor deposition (CVD), copper grain growth proceeds more rapidly than nucleation, resulting in the same problem of a rough surface. Large grains are also undesirable because they can impinge upon one another within submicron structures such as a contact or line structure and close off a contact opening or via before the structure has been completely filled.

The problem of electromigration of the metal atoms in the formation of an IC must also be considered. In electromigration, metal atoms are transported along grain boundaries, driven by the force exerted by flowing electrons under high current densities. As a result, areas devoid of metal atoms (voids) form at one end of the substrate, and areas with an overabundance of metal atoms (extrusions) form at the other end of the metal lines. This leads to an increased probability of circuit failure in the area of the voids.

Attempts to overcome these problems have been only partially successful. For example, a two-step technique for depositing a copper film on a substrate surface has been disclosed by Chen et al. In the first step, a thin copper layer is deposited by CVD, resulting in a copper layer with a high density of small nuclei. In the second step, the remainder of the film is grown by depositing copper by PVD, which is less expensive than CVD as previously stated. However, this method suffers from several drawbacks. One drawback is that two separate deposition chambers must be used to deposit a single film. This results in decreased processing efficiency and throughput, and adds time and expense to the process. Another drawback is that the method does not solve the previously discussed problem of electromigration of copper atoms leading to voids. Thus, this method is not completely satisfactory.

Attempts to solve the problem of electromigration do not address the problem of a rough surface morphology. For example, there have been attempts to impede electromigration using a doping process. The methods involve doping the copper metallization film with a small amount of impurity metal by sputtering the dopant along with copper from an alloyed target of copper and the dopant metal. The dopant metal lodges in the copper grain boundaries and thus slows the rate of grain boundary diffusion. However, as previously stated, this method still produces an unacceptable surface morphology.

What is needed, then, is a method of depositing a copper film having a controlled morphology and with impeded electromigration of copper atoms so that the resulting copper film contains a smooth mirror-like surface and has no voids.

### SUMMARY OF THE INVENTION

A method is disclosed whereby a copper film having a controlled morphology and impeded electromigration is deposited onto a substrate or wafer surface. The method comprises depositing an initial wetting layer of a metal dopant to provide a seed layer on a substrate or wafer, and subsequently depositing a thicker or bulk copper layer over the metal seed layer. The dopant metal may be, for example, aluminum (Al), tin (Sn) or magnesium (Mg), and is deposited from a pure target. The bulk copper is deposited, preferably by a physical vapor deposition (PVD) process, onto the dopant seed layer. In one embodiment of the present invention, the copper may be deposited at a temperature greater than ½ the melting temperature of the dopant metal, such that the dopant metal diffuses into the bulk copper as the copper is deposited. Alternatively, the dopant seed layer and deposited copper are annealed to diffuse the dopant into the bulk copper. In yet another alternative process, the wetting or seed layer is first deposited on the substrate or wafer, and then copper is deposited onto the wetting layer such that no diffusion occurs and a separate, distinct wetting layer remains between the underlying substrate material and the copper film.

The disclosed methods deposit a copper film that has controlled morphology and no voids on a substrate or wafer. The method thus overcomes both problems of a rough surface morphology and areas of voids due to electromigration of copper atoms. A semiconductor wafer is thus produced having a copper interconnect film with a controlled surface morphology.

### Brief Description of the Drawings

FIG. 1 is a schematic of a processing chamber containing a substrate processed by one embodiment of the invention.

FIG. 2 is a schematic of a substrate processed by an alternative embodiment of the invention.

FIG. 3 is an IPVD processing chamber.

### Detailed Description

With reference to FIG. 1, a conventional arrangement for a target 10 and wafer or substrate 12 in a processing chamber 13 is shown. Using one embodiment of the method of the invention, an alloying metal, hereinafter referred to as a metal dopant 15, is deposited by a physical vapor deposition (PVD) process such as sputtering onto the surface 17 of a semiconductor substrate 12 to form a first layer 19 that is a wetting layer or a seed layer. A bulk copper layer 21 is subsequently deposited by a PVD process onto the first layer 19. The resulting sputtered copper film 23 has a controlled morphology, defined as having a substantially continuous smooth surface without voids.

The dopant 15 can serve several roles. The dopant 15 has the effect of improving the surface morphology of a subsequently deposited copper film 23, thereby providing a smoother final copper surface. The dopant 15 enhances nucleation by providing more nuclei, which inhibits grain growth to thereby provide a high density of small copper crystals. The dopant 15 further prevents the copper grains from coalescing. The dopant 15 also suppresses copper electromigration by filling copper grain boundaries and thus suppress voids in the resulting film 23, and may also form a protective, anti-corrosion layer at the copper surface.

The dopant 15 is selected such that it will naturally wet the substrate surface 17 and provide a smooth nucleation layer for further film 23 growth. The dopant 15 may also be selected such that it will diffuse into copper. Depending on the degree of solubility of the dopant 15 in copper, the dopant may diffuse evenly, or advantageously may segregate in the copper grain boundaries. If alloyed with copper 25, the dopant 15 will advantageously provide a low surface energy alloy. Several doping metals have been suggested to form a wetting layer 19 for a subsequently deposited copper layer 21 and which serve the purpose of stuffing the copper grain boundaries through alloying to suppress electromigration. Potential dopants 15 include aluminum (Al), tin (Sn) and magnesium (Mg).

The dopant metal 15 is preferably deposited to form a thin, pure layer 19 of about 10-50 Å to serve as a wetting layer or seed layer for subsequently deposited copper. The dopant metal 15 is deposited from a substantially pure target 10, defined as a target having a purity of at least about 99.999%. In one embodiment of the present invention, upon subsequent ambient temperature or low temperature deposition of a thicker or bulk copper layer 25, the wetting layer provides nucleation sites for the copper as it is deposited, thereby suppressing rapid copper grain growth. A smoother surface morphology is thereby obtained. In this embodiment, the thin wetting layer does not diffuse into the copper due to the absence of an elevated temperature sufficient for that purpose, and thus a separate, distinct wetting layer remains between the underlying substrate material and the copper film.

In another embodiment of the present invention, the bulk copper 25 is deposited at an ambient or low temperature, as above, but is subsequently annealed with the dopant 15 by heating the substrate 12 to an elevated temperature to facilitate grain growth and to anneal the copper 25 with wetting layer 19. The annealing temperature is sufficiently high to allow diffusion of the dopant metal 15 into the bulk copper 25. The annealing temperature may be, for example, greater than ½ the melting temperature of the dopant metal 15. Typically, the annealing temperature should be at least about 400° C. Advantageously, the temperature is less than the melting temperature of the dopant metal 15. Diffusion should be substantially complete, resulting in a substantially uniform dispersion of the dopant through the copper film. In an embodiment of the present invention, a dopant material is selected that is insoluble in copper. Therefore, any alloy formed will be metastable. Moreover, the dopant tends to segregate at grain boundaries in the copper, thus impeding electromigration. Heating of the substrate 12 to the annealing temperature may be accomplished by regulating the temperature of the susceptor 27 supporting the substrate 12, typically by applying a radiofrequency (RF) bias by means of an RF power supply 28 and matching unit 29.

In yet another alternative embodiment of the present invention, upon subsequent elevated temperature deposition of a thicker or bulk copper layer 25, the dopant metal 15 comprising the wetting layer 19 diffuses into the bulk copper 25 as it is deposited. This diffusion of dopant metal 15 into the bulk copper 25 provides a smooth nucleation layer 19 for further film growth, and thus enables formation of the desired smooth surface morphology of the sputtered copper film 23. Further, the diffusion of dopant metal 15 into copper grain boundaries prevents voids in the film 23 by retarding electromigration of copper atoms. The elevated temperature may be, for example, greater than ½ the melting temperature of the dopant metal 15. Typically, the elevated temperature should be at least about 400° C. Advantageously, the temperature is less than the melting temperature of the dopant metal 15.

The processing chamber 13 is a physical vapor deposition chamber, such as an ionized physical vapor deposition (IPVD) chamber to deposit a thin metal film 23 on a substrate 12 such as a semiconductor wafer 12. For example, U.S. Pat. No. 5,659,363 entitled INDUCTIVELY COUPLED PLASMA SPUTTER CHAMBER WITH CONDUCTIVE MATERIAL SPUTTERING CAPABILITIES which is assigned to Tokyo Electron Limited, and U.S. Pat. No. 5,187,739 entitled APPARATUS FOR DEPOSITING MATERIAL INTO HIGH ASPECT RATIO HOLES which is assigned to International Business Machines Corporation, each of which is expressly incorporated by reference herein in its entirety, describe IPVD systems which may be used in the present invention to achieve high metal ionizations.

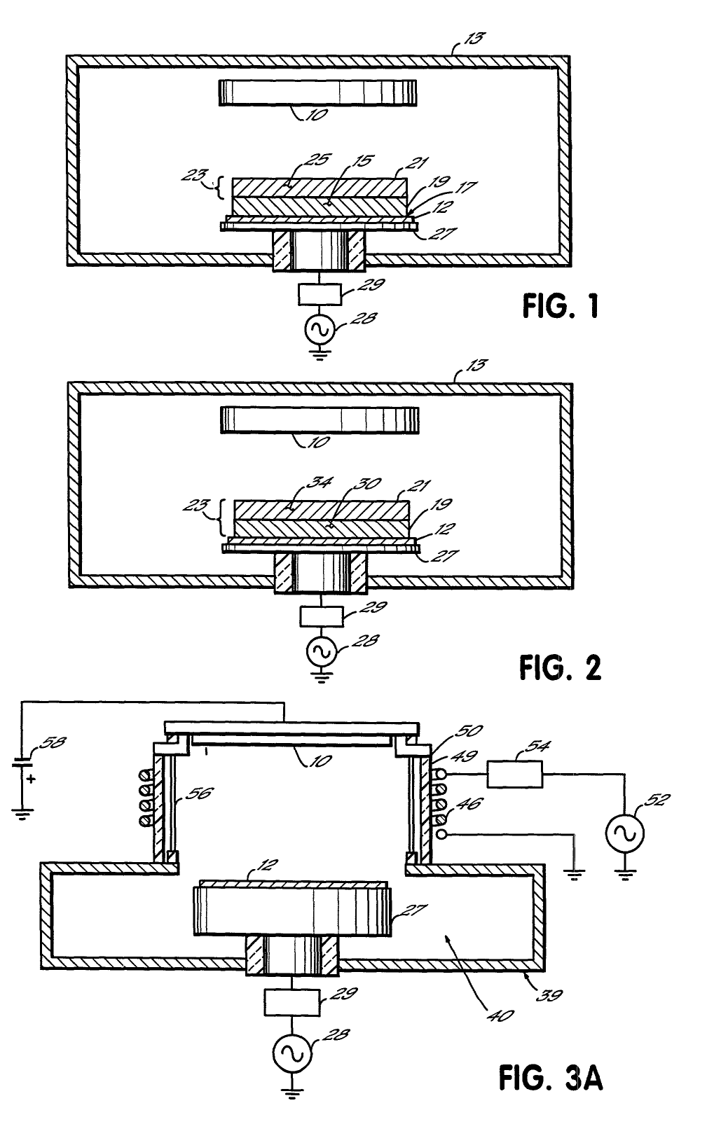

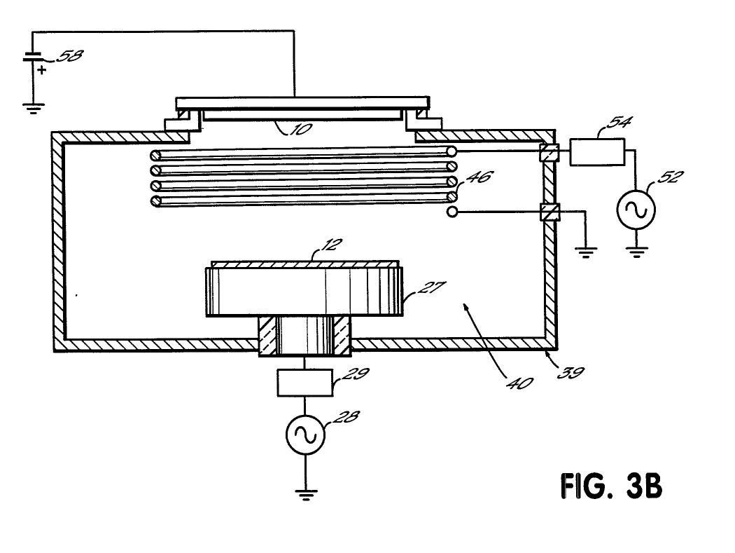

With reference to FIG. 3A and FIG. 3B, a reaction chamber 39 for IPVD is shown. Materials to be deposited by IPVD are sputtered from a target 10. In a sputtering process, a substrate 12 such as a semiconductor wafer 12 is mounted in a vacuum reaction chamber 39 whose interior 40 is filled with a process gas. The gas, upon electrical excitation generated by magnetic coupling of the chamber 39 to a radiofrequency (RF) powered excitation coil 46, produces a high density plasma. The plasma causes a substantial fraction of the material sputtered from the target 10 to be converted to positive ions before reaching the wafer 12.

The vacuum reaction chamber 39 has as part of its wall 49 a dielectric material 50. As shown in FIG. 3A, the helical electrically conducting coil 46 may be disposed outside and concentric with the chamber 39. The coil 46 is energized from a supply of RF power 52 by a suitable impedance matching system 54. The dielectric material 50 is protected from metal deposition by an arrangement of shields 56 which are capable of passing an RF magnetic field into the interior 40 region of the chamber 39 while excluding as much as possible such deposition of metal on the dielectric material 50 as would tend to form conducting paths for circulating currents generated by the magnetic fields. Such currents are undesirable because they lead to ohmic heating and to reduction of the magnetic coupling of the excitation coils 46 to the plasma, so that plasma densities are reduced and the process results deteriorate.

As shown in FIG. 3B, in an alternative embodiment of a reaction chamber 39 a plasma in the chamber interior 40 is generated by means of a coil 46 located in the chamber interior 40. In this alternative embodiment, as described in the aforementioned U.S. Pat. No. 5,178,739, neither dielectric chamber walls 50 nor special shields 56 are required.

As a result of excitation of the process gas using either embodiment of the reaction chamber 39, a high density plasma is generated in the interior 40 of the chamber 39. The high density plasma is concentrated in the region between the target 10 and the wafer 12. A negative bias on the wafer 12 causes ions to be accelerated normal to the wafer 12. The negative bias may arise either with the wafer 12 electrically isolated, such as by immersion of the wafer 12 in a plasma, or because of an applied RF voltage from an RF power supply 58.

Methods are thus disclosed for controlling the morphology and impeding electromigration of sputtered copper films. In one embodiment, copper is deposited onto a seed layer or wetting layer of a dopant metal by PVD at an ambient or low temperature. In another embodiment, the copper and wetting or seed layer are subsequently heated to a temperature of at least about 400° C. to anneal the copper and dopant metal layers. In yet another alternative embodiment, copper is deposited by a PVD process onto the seed layer at a temperature greater than about 400° C. to diffuse the dopant metal into the copper layer as it is being deposited. The copper layer may be deposited by an IPVD process. The result is a copper film with a smooth surface and no voids.

While the present invention has been illustrated by the description of embodiments thereof, and while the embodiments have been described in considerable detail, they are not intended to restrict or in any way limit the scope of the appended claims to such detail. Additional advantages and modifications will readily appear to those skilled in the art. For example, it is possible to use operating parameters for IPVD that are outside of the disclosed ranges. The invention in its broader aspects is therefore not limited to the specific details, representative apparatus and method and illustrative examples shown and described. Accordingly, departures may be made from such details without departing from the scope or spirit of applicant's general inventive concept.

What is claimed is:

1. A method for forming a copper film with controlled morphology on a substrate comprising depositing a seed layer of a metal dopant by physical vapor deposition (PVD) then subsequently depositing a copper layer onto said seed layer by PVD and diffusing said dopant into said copper.

2. The method of claim 1 wherein said copper layer is deposited at an ambient temperature and said substrate is subsequently heated to an annealing temperature sufficient to diffuse said copper into said dopant.

3. The method of claim 2 wherein the annealing temperature is greater than about ½ the melting temperature of the dopant.

4. The method of claim 2 wherein the annealing temperature is at least about 400° C.

5. The method of claim 1 wherein the dopant is sputtered from a substantially pure target.

6. The method of claim 1 wherein the dopant provides a low surface energy when the dopant is alloyed with copper.

7. The method of claim 1 wherein the dopant is selected from the group consisting of aluminum, tin and magnesium.

8. The method of claim 1 wherein said copper layer is deposited at an elevated temperature sufficient to cause said diffusing to occur concurrently with said depositing of copper.

9. The method of claim 8 wherein said elevated temperature is greater than about ½ the melting temperature of the dopant.

10. The method of claim 8 wherein said elevated temperature is at least about 400° C.

11. The method of claim 1 wherein the seed layer is deposited to a thickness of between about 10 Å and about 50 Å.

12. A method for forming a copper film with controlled morphology on a substrate comprising depositing a wetting layer onto said substrate by physical vapor deposition (PVD) and thereafter depositing copper onto said wetting layer by PVD to form a copper layer.

13. The method of claim 12 wherein the wetting layer comprises a metal selected from the group consisting of aluminum, tin and magnesium.

14. The method of claim 12 wherein the wetting layer is deposited to a thickness of about 10-50 Å.

15. The method of claim 12 wherein the wetting layer is sputtered from a substantially pure target.

16. The method of claim 12 wherein the copper layer is deposited at an elevated temperature sufficient to cause the wetting layer to diffuse into the copper as it is deposited.

17. The method of claim 16 wherein said elevated temperature is greater than about ½ the melting temperature of the dopant.

18. The method of claim 16 wherein said elevated temperature is at least about 400° C.

19. The method of claim 16 wherein the copper layer is deposited at an ambient temperature and said substrate is subsequently heated to an annealing temperature sufficient to diffuse said wetting layer into the copper.

20. The method of claim 19 wherein the annealing temperature is greater than about ½ the melting temperature of the dopant.

21. The method of claim 19 wherein the annealing temperature is at least about 400° C.

22. A semiconductor substrate comprising a copper interconnect film with a controlled morphology surface comprising an alloy of a dopant metal and copper.

23. The substrate of claim 22 wherein said dopant metal is selected from the group consisting of aluminum, tin and magnesium.

24. The substrate of claim 22 wherein said dopant provides a low surface energy to said film.

25. The substrate of claim 22 wherein said dopant suppresses copper electromigration.

26. The substrate of claim 22 wherein the alloy is metastable.

27. The substrate of claim 22 wherein dopant metal is segregated at grain boundaries in the copper.

28. A semiconductor substrate comprising a copper interconnect film with controlled morphology comprising a first layer of a sputtered metal selected from the group consisting of aluminum, tin and magnesium and a second layer of sputtered copper on said first layer.
